(19) United States
(12) Patent Application Publication
(10) Pub. No.: US 2026/0038580 A1
(43) Pub. Date: Feb. 5, 2026

(54) Method and Apparatus for Sharing a Sense Amplifier between Memory Cells of a Memory Device

(71) Applicant: Micron Technology, Inc., Boise, ID (US)

(72) Inventors: Yang Lu, Boise, ID (US); John David Porter, Boise, ID (US); Luoqi Li, Meridian, ID (US); Wesley Bryan Butler, Boise, ID (US); Christopher John Kawamura, Boise, ID (US); Kang-Yong Kim, Boise, ID (US)

(73) Assignee: Micron Technology, Inc., Boise, ID (US)

(21) Appl. No.: 18/791,079

(22) Filed: Jul. 31, 2024

(51) Int. Cl. G11C 11/4091; G11C 11/4076; G11C 11/4094

(52) U.S. Cl. CPC G11C 11/4091; G11C 11/4076; G11C 11/4094

(57) ABSTRACT

Apparatuses and techniques for sharing a sense amplifier between memory cells of a memory device are described. To enable sharing of a sense amplifier between two memory cells, a memory device includes switching devices that selectively couple bitlines of two memory cells to a single sense amplifier. During a first time period, for a differential sense amplifier, the switching devices are controlled to connect terminals of the sense amplifier to bitlines of a first memory cell and to disconnect bitlines of a second memory cell from the terminals of the sense amplifier. During a second time period, the switching devices are controlled to connect terminals of the sense amplifier to the bitlines of the second memory cell and disconnect the bitlines of the first memory cell from the terminals of the sense amplifier. Accordingly, a single sense amplifier may be utilized to read the stored values from different memory cells.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for sharing a sense amplifier between memory cells of a memory device are described with reference to the following drawings. The same numbers are used throughout the drawings to reference like features and components:

FIG. 1 illustrates example apparatuses that can implement aspects of sharing a sense amplifier between memory cells of a memory device;

FIG. 2 illustrates example computing systems that can implement aspects of sharing a sense amplifier between memory cells of a memory device;

FIG. 3 illustrates example approaches to storing data within rows of a memory array to support sharing a sense amplifier between memory cells of a memory device;

FIG. 4 illustrates an example memory device in which aspects of sharing a sense amplifier between memory cells of a memory device can be implemented;

FIG. 5 illustrates an example arrangement of circuits that can implement aspects of sharing a sense amplifier between memory cells of a memory device;

FIG. 6 illustrates aspects of an example usage-based-disturbance mitigation operation that is performed by an example usage-based-disturbance mitigation circuit;

FIG. 7 illustrates aspects of an example sense amplifier that can be shared between memory cells of a memory device;

FIG. 8 illustrates aspects of another example sense amplifier that can be shared between memory cells of a memory device;

FIG. 9 illustrates an example timing diagram for implementing aspects of sharing a sense amplifier between memory cells of the memory device of FIG. 8; and

FIG. 10 illustrates an example method for implementing aspects of sharing a sense amplifier between memory cells of a memory device.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification, respectively. In some implementations, however, more-reliable memories can sacrifice bit density, power efficiency, and simplicity.

Generally, a memory device is expected to service memory requests from a host device within predetermined time periods and/or with predictable delay durations. These constraints mean that the memory device prioritizes memory requests from an external entity, such as a memory controller of a host device. A modern memory device, however, has additional expectations beyond servicing memory requests. For example, to create a more-reliable memory, a memory device is expected to combat attacks from bad actors, such as usage-based-disturbance (UBD) attacks, which are described below. Thus, a memory device may perform usage-based-disturbance mitigation operations in conjunction with servicing memory requests. As another example, a memory device is expected to counteract data bit errors that arise from manufacturing defects or randomized events, which errors can be exacerbated by reading data bit values at higher rates.

To meet the demands for physically smaller memories, memory devices can be designed with higher chip densities for the memory cells. Increasing chip density, however, can increase the electromagnetic coupling between proximate rows of memory cells due, at least in part, to a shrinking distance between these rows. With this undesired electromagnetic coupling (e.g., capacitive coupling), activation (or charging) of a first row of memory cells can sometimes negatively impact the integrity of the digital values stored in a nearby second row of memory cells. This phenomenon is referred to herein as usage-based disturbance. Activation of the first row can generate interference, or crosstalk, that causes the second row to experience a voltage fluctuation. In some instances, this voltage fluctuation can cause a state, or value, of a memory cell in the second row to be incorrectly determined by a sense amplifier. Consider an example in which a state of a memory cell in the second row is a logical “1” (e.g., a high voltage). In this example, the voltage fluctuation can cause a sense amplifier that is reading the memory cell to incorrectly determine the state of the cell to be a logical “0” (e.g., a low voltage) instead of a logical “1.” Left unchecked, this interference can lead to memory errors or data loss within the memory device.

In some circumstances, a particular row of memory cells is activated repeatedly in an unintentional or intentional manner, which can be part of a malicious act. Such a row that is repeatedly activated is referred to herein as an aggressor row. Consider, for instance, that memory cells in an R^{th} row are subjected to repeated activation, which causes one or more memory cells in a proximate row (e.g., an adjacent row) to change states. Here, a proximate row can include an R+1 row, which is an adjacent row; an R+2 row; an R−1 row, which is another adjacent row; and/or an R−2 row. These proximate rows are referred to herein as victim rows. The effect of memory states being unintentionally changed in these manners is referred to as a usage-based disturbance. The occurrence of usage-based disturbance can lead to the corruption or changing of contents within the affected row of memory. As described herein below, to combat the negative effects of usage-based disturbance, a memory device can perform usage-based-disturbance mitigation operations.

Memory devices store data using memory cells. The stored data can include normal data or usage-based-disturbance data, just to name a couple of examples. With some volatile memory devices, such as those using dynamic random-access memory (DRAM), each memory cell stores data (e.g., one bit of data) using a voltage level (e.g., a high or low voltage level) that is held by a capacitor. By way of example only, a memory cell can include one transistor coupled to one capacitor to store one bit of data or can include two transistors coupled to two capacitors to store one bit of data using differential logic. To read data in the memory cell, a sense amplifier senses an indication of the voltage stored on the one or more capacitors.

Especially as memory devices are designed with larger storage capacities, the layout area for the memory devices becomes constrained. A memory cell array may be arranged into multiple sub-arrays. In a typical memory device, each respective sub-array is associated with a respective set of sense amplifiers. Each respective sense amplifier is assigned to sense the voltage from a respective memory cell in an activated row in the associated sub-array. Thus, a row of sense amplifiers may be configured to sense the voltages of the memory cells of an activated row without employing an intervening switching mechanism between a respective sense amplifier and a respective memory cell. However, each sense amplifier may be formed from multiple transistors. The sense amplifiers within a memory device can therefore consume a significant amount of area of an integrated circuit (IC) chip, which increases the cost of memory devices.

In approaches that are described herein, a sense amplifier is shared between two or more memory cells of a memory device using switches to allow for more efficient utilization of space within a memory device as well as more efficient routing of bitline paths. Further, in some aspects, power saving can be obtained by sharing sense amplifiers among multiple memory cells of different sub-arrays of a memory device.

In example implementations, to enable the sharing of a sense amplifier between at least two memory cells, a memory device includes switching devices that selectively couple bitlines of two memory cells to a single sense amplifier. During a first time period, the switching devices are controlled to connect at least one terminal of the sense amplifier to at least one bitline coupled to a first memory cell and to disconnect from the at least one terminal of the sense amplifier at least one bitline coupled to a second memory cell. During a second time period, the switching devices are controlled to connect the at least one terminal of the sense amplifier to the at least one bitline of the second memory cell and to disconnect the at least one bitline of the first memory cell from the at least one terminal of the sense amplifier.

If each memory cell includes a single capacitor, the sense amplifier may have a single terminal that is selectively connected to a bitline that is coupled to a targeted memory cell. If each memory cell includes two capacitors (e.g., employing differential logic to store one data bit), the sense amplifier may have two terminals that are selectively connected to two bitlines that are coupled to a targeted memory cell. Accordingly, a single sense amplifier may be utilized to read the stored values from multiple memory cells, including memory cells that are parts of different memory arrays or sub-arrays. In these manners, the limited area of an IC chip can be used more efficiently to lower costs of memory devices.

### Example Operating Environments

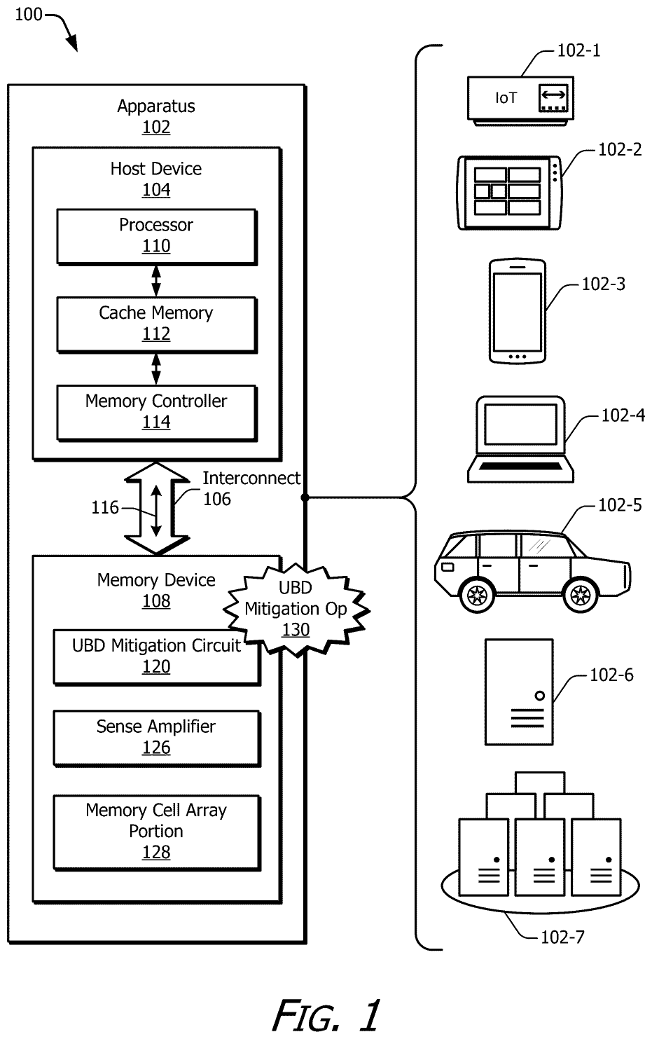

FIG. 1 illustrates, at 100 generally, an example operating environment including an apparatus 102 that can implement aspects of sharing a sense amplifier between memory cells of a memory device. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7. The server computer 102-6 or the server cluster 102-7 may be part of cloud computing infrastructure, a data center, a portion thereof (e.g., a printed circuit board (PCB)), and so forth. Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, medical device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and at least one memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit (CPU), graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) or synchronous memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests (e.g., read data or write confirmation) that are received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., unidirectional bus, bidirectional bus, or memory bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity or lower cost relative to memory at higher hierarchical levels. Accordingly, the memory device 108 can form at least part of the main memory of the apparatus 102. Additionally or alternatively, the memory device 108 may form at least part of a cache memory, a storage memory, or a system-on-chip of the apparatus 102.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114.

Thus, this document describes with reference to FIG. 1 an example computing system architecture having at least one host device 104 coupled to a memory device 108. Two or more memory components (e.g., modules, dies, bank groups, or banks) may share the electrical paths or couplings of the interconnect 106 that can extend between the host device 104 and the memory device 108. The interconnect 106 can include at least one command-and-address bus (CA bus) and at least one data bus (DQ bus), which are not separately depicted. The command-and-address bus can transmit addresses and commands from the memory controller 114 of the host device 104 to the memory device 108. In some cases, the command-and-address bus may exclude the propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

In example implementations, the memory device 108 includes at least one usage-based-disturbance mitigation circuit 120 (UBD mitigation circuit 120). The UBD mitigation circuit 120 can be implemented using, for instance, programmable logic circuitry, fixed logic circuitry, some combination thereof, and so forth. The UBD mitigation circuit 120 can be arranged or organized in any manner.

In example operations, the UBD mitigation circuit 120 mitigates usage-based disturbance for one or more banks that are associated with (e.g., that are part of) the memory device 108 using at least one usage-based-disturbance mitigation operation 130 (UBD mitigation operation 130). This mitigation can include detecting a condition associated with usage-based disturbance, such as the presence of an aggressor row, and initiating a refresh of one or more victim rows associated with the detected condition of the aggressor row. The UBD mitigation circuit 120 can employ various strategies for detecting and mitigating usage-based-disturbance conditions, including tracking row activations in memory that is coupled to and read by sense amplifiers.

The memory device 108 also includes at least one sense amplifier 126 coupled to at least one memory cell array portion 128 of multiple memory cell array portions of the memory device 108. As further described herein, the sense amplifier 126 can be selectively shared between two or more memory cell array portions 128. For example, the sense amplifier 126 can be connected to a first memory cell array portion 128 and disconnected from a second memory cell array portion 128 during a first time period. During a second time period, the sense amplifier 126 can be disconnected from the first memory cell array portion 128 and connected to the second memory cell array portion 128. Accordingly, a single sense amplifier 126 may be shared between two more memory cells, which may be part of different memory cell array portions 128. To do so, respective switching devices can be coupled between the sense amplifier 126 and respective memory cells.

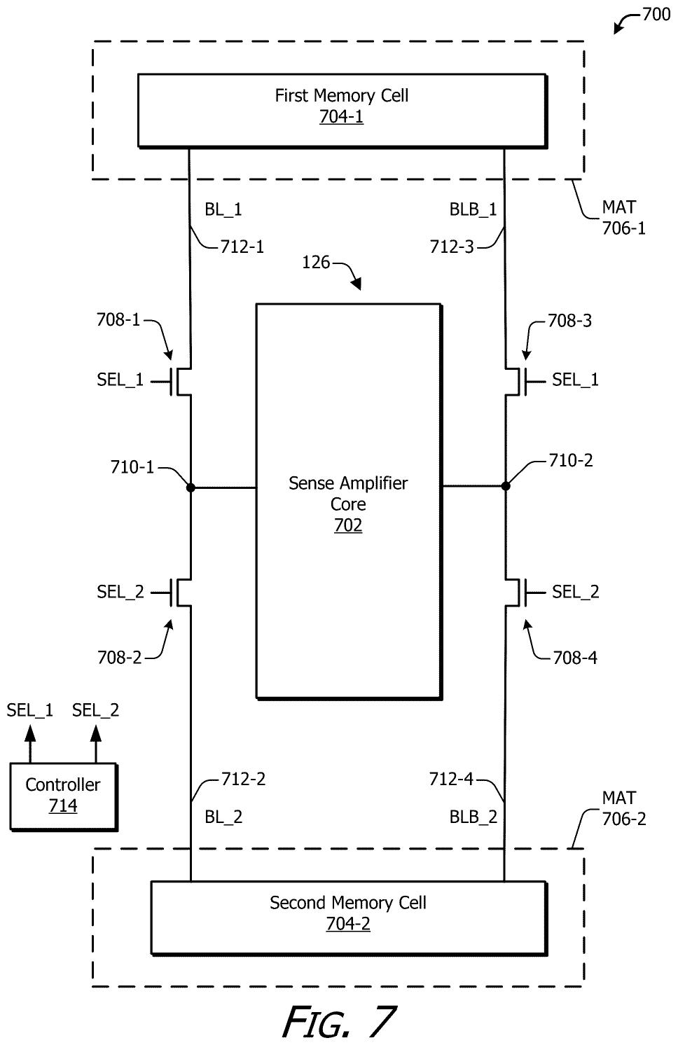

Although the example of FIG. 1 is illustrated as showing a single sense amplifier 126, a memory device 108 can include multiple sense amplifiers that are each shared between two or more memory cells, which may be part of two or more memory cell array portions 128 of the memory device 108. For example, in a particular aspect, multiple sense amplifiers are included in which each sense amplifier is shared between at least two memory cells of the memory cell array portions 128. Examples of these implementations are described below with reference to FIG. 7.

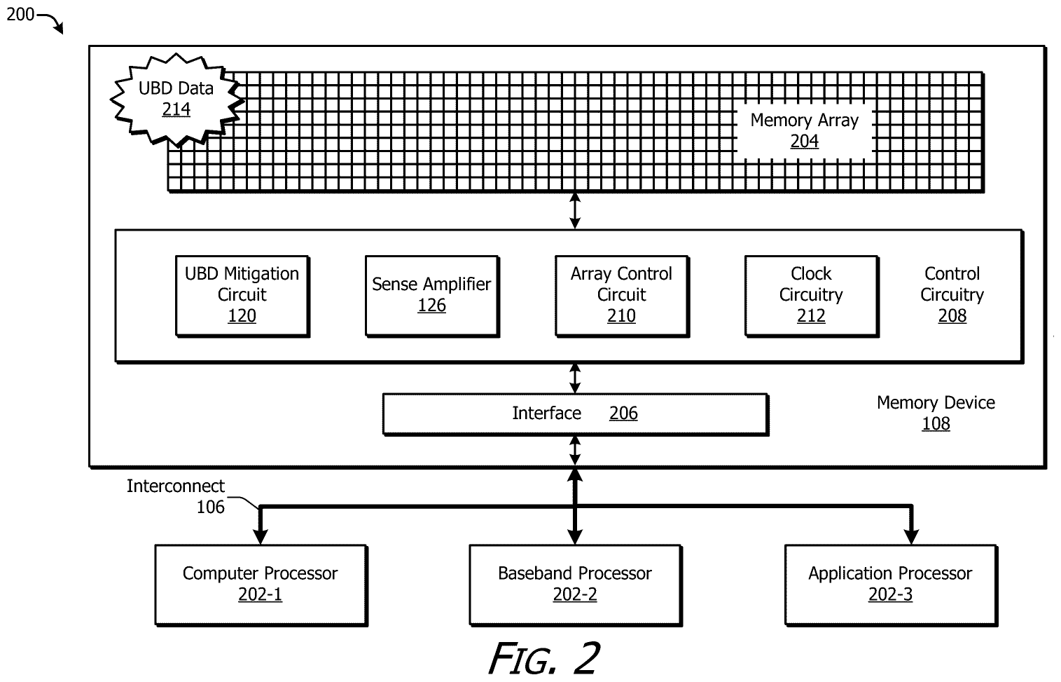

FIG. 2 illustrates examples of a computing system 200 that can implement aspects of sharing a sense amplifier between memory cells of a memory device. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry or central circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may additionally or alternatively manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the UBD mitigation circuit 120, at least one sense amplifier 126, at least one array control circuit 210, and at least one instance of clock circuitry 212. In some implementations, the UBD mitigation circuit 120 and the at least one sense amplifier 126 are part of the control circuitry 208, as shown in FIG. 2. In other implementations, the UBD mitigation circuit 120 or the sense amplifier 126 are considered at least partly separate from the control circuitry 208 from a logical or physical perspective.

The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also include an internal clock generator or use an internal clock signal to synchronize memory components. The clock circuitry may further provide timer functionality.

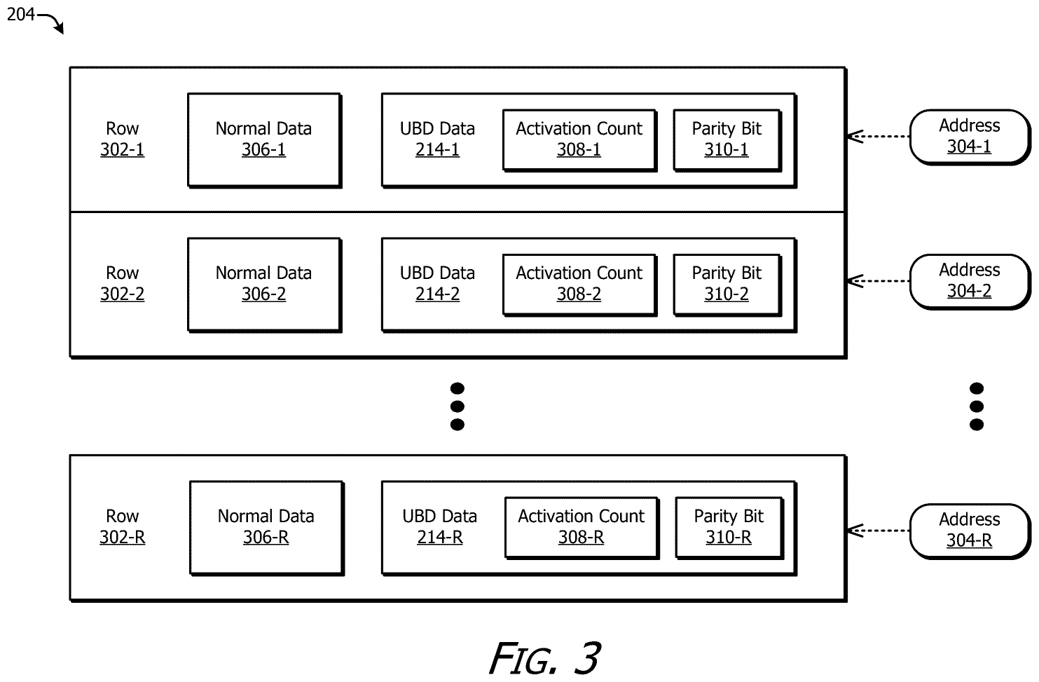

The UBD mitigation circuit 120 can be coupled to a set of memory cells within the memory array 204 that store usage-based-disturbance data 214 (UBD data 214). The usage-based-disturbance data 214 can include information such as an activation count, which represents a quantity of times one or more rows within the memory array 204 have been activated (or accessed) by the memory device 108. In example implementations, each row of the memory array 204 includes or is otherwise associated with a subset of memory cells that stores the usage-based-disturbance data 214 associated with that row, which is further described with reference to FIG. 3. The at least one sense amplifier 126 is coupled to at least two memory cells and may be shared between at least two portions of the memory array 204 in which each portion includes a subset of memory cells.

The interface 206 can couple the control circuitry 208 or the memory array 204 directly or indirectly to the interconnect 106. In some implementations, the UBD mitigation circuit 120, the at least one sense amplifier 126, the array control circuit 210, and the clock circuitry 212 can be part of a single component (e.g., the control circuitry 208). In other implementations, one or more of the UBD mitigation circuit 120, the sense amplifier 126, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and a processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, memory module (e.g., a single in-line memory module (SIMM), a dual in-line memory module (DIMM), or a Compute Express Link® (CXL®) memory module), or memory integrated circuit, just to name a few examples. Separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or combined in a single package or a system-on-chip.

As shown in FIG. 2, the processors 202 may include a computer processor 202-1, a baseband processor 202-2, and an application processor 202-3, which are coupled to the memory device 108 through the interconnect 106. The processors 202 may include or form a part of a central processing unit (CPU), graphics processing unit (GPU), system-on-chip (SoC), application-specific integrated circuit (ASIC), or field-programmable gate array (FPGA). In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). Examples of the memory array 204 are further described with reference to FIG. 3.

FIG. 3 illustrates example approaches to storing data within rows of a memory array 204 to support sharing a sense amplifier between memory cells of a memory device. As illustrated, the memory array 204 includes multiple rows 302 of memory cells. For example, the memory array 204 can include rows 302-1, 302-2, . . . , 302-R, where R represents a positive integer. Each row 302 is respectively associated with an address 304 (e.g., a row address, a memory row address, or a memory address) of multiple addresses 304-1, 304-2, . . . , 304-R. For example, a first row 302-1 has a first address 304-1, a second row 302-2 has a second address 304-2, and an R^{th} row 302-R has an R^{th} address 304-R.

Each of the rows 302 can store normal data 306 within a first subset of the memory cells associated with that row 302. The normal data 306 represents data that is read from or written to the memory device 108 during normal memory input/output operations (e.g., during normal read or write operations for user data) and may further include check bits for a codeword generated by an error handling circuit as a mechanism to detect or correct errors in user data. The normal data 306, for example, can include data that is transmitted by the memory controller 114 and is written to one or more rows 302 of the memory array 204.

In example implementations, in addition to the normal data 306, each of the rows 302 can store usage-based-disturbance data 214 within a second subset of the memory cells associated with that row 302. The usage-based-disturbance data 214 includes information that enables the UBD mitigation circuit 120 to mitigate the potential effects of usage-based disturbance. In example aspects, the usage-based-disturbance data 214 includes an activation count 308. With the activation count 308, the memory device 108 can keep track of a quantity of accesses or activations of the corresponding memory row 302. In some example implementations, the usage-based-disturbance data 214 can also include a count of how many times a neighboring row (e.g., an adjacent or other proximate row) is refreshed in order to mitigate usage-based disturbance. Each of these counts provide an example mechanism by which the memory device 108 can monitor for usage-based disturbance and determine when to refresh victim rows to reduce the risk of usage-based disturbance corrupting data.

In the example shown in FIG. 3, the first row 302-1 stores first normal data 306-1 within a first subset of memory cells of the first row 302-1 and stores first usage-based-disturbance data 214-1 within a second subset of memory cells of the first row 302-1. The first usage-based-disturbance data 214-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 214-2 within a second subset of memory cells within the second row 302-2. The second usage-based-disturbance data 214-2 includes a second activation count 308-2, which represents a quantity of times the second row 302-2 has been activated since a last refresh. Additionally, the R^{th} row 302-R stores R^{th} normal data 306-R within a first subset of memory cells within the R^{th} row 302-R and stores R^{th} usage-based-disturbance data 214-R within a second subset of memory cells within the R^{th} row 302-R. The Rih usage-based-disturbance data 214-R includes an R^{th} activation count 308-R, which represents a quantity of times the R^{th} row 302-R has been activated since a last refresh.

The usage-based-disturbance data 214 can also include information or can be formatted (e.g., coded) in such a way as to support error detection. In this example, the usage-based-disturbance data 214 includes a parity bit 310. In particular, the usage-based-disturbance data 214-1, 214-2, and 214-R respectively includes a parity bit 310-1, 310-2, and 310-R. Other implementations are also possible in which the usage-based-disturbance data 214 is coded in a manner that supports any given error detection test, such as an error-correcting-code (ECC) check. The parity bit 310, or other check bit(s) that are stored as part of the usage-based-disturbance data 214, can be used to check the accuracy or correctness of the activation count 308. Although techniques for detecting a condition associated with usage-based disturbance are primarily described herein with respect to using an activation count 308, these techniques can be applied generally to detecting a condition based on any type of information that is represented by the usage-based-disturbance data 214, including error-detection techniques.

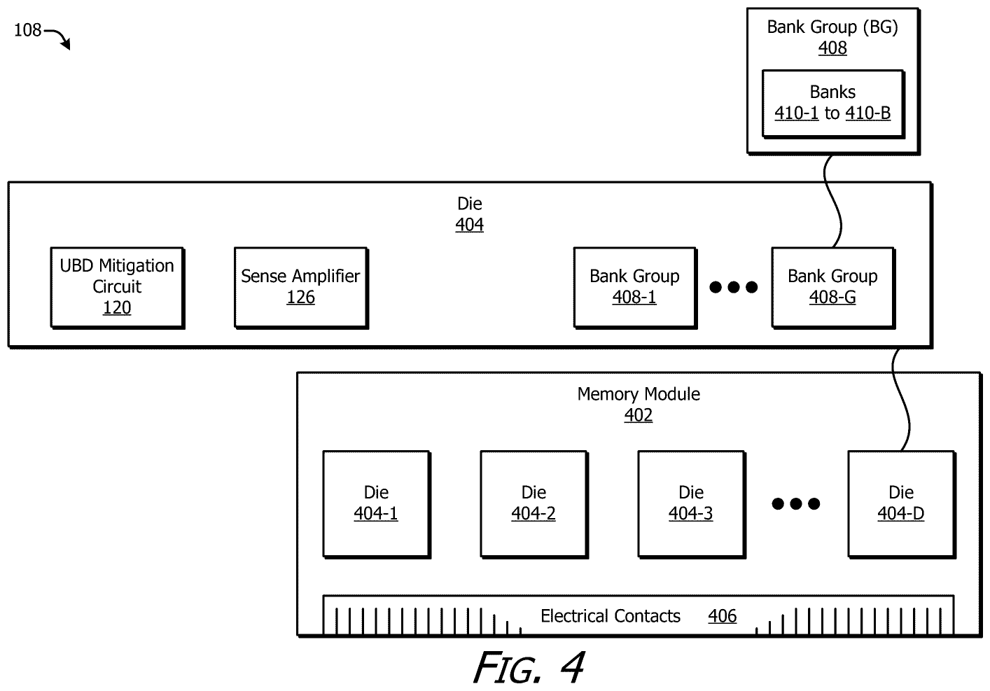

FIG. 4 illustrates an example memory device 108 in which aspects of sharing a sense amplifier between memory cells of a memory device can be implemented. As shown, the memory device 108 includes a memory module 402, which can include multiple dies 404. As illustrated, the memory module 402 includes a first die 404-1, a second die 404-2, a third die 404-3, and a D^{th} die 404-D, with D representing a positive integer. The memory module 402 can be a SIMM or a DIMM, for instance. As another example, the memory module 402 can interface with other components via a bus interconnect (e.g., a Peripheral Component Interconnect Express (PCIe®) bus). The memory module 402 can also be implemented as a CXL® device. The memory device 108 illustrated in FIGS. 1 and 2 can correspond, for example, to a die 404, to multiple dies (or dice) 404-1 through 404-D, or to a memory module 402 with two or more dies 404. As shown, the memory module 402 can include one or more electrical contacts 406 (e.g., pins) to interface the memory module 402 to other components.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size to each other or may have different sizes. Generally, each die 404 may be similar to another die 404 or may be different in size, shape, data capacity, or control circuitries. The dies 404 may also be positioned on a single side or on multiple sides of the memory module 402 or may be disposed within a housing of the memory module 402.

In example implementations, one or more of the dies 404-1 to 404-D include the UBD mitigation circuit 120, one or more sense amplifiers 126, and multiple bank groups 408-1 . . . 408-G, with G representing a positive integer. Each bank group 408 includes at least two banks 410, such as multiple banks 410-1 . . . 410-B, with B representing a positive integer. In some implementations, the die 404 includes multiple instances of the UBD mitigation circuit 120, each of which mitigates usage-based-disturbance across at least one of the banks 410. Generally, a given circuit can operate with respect to a single bank 410, multiple banks 410-1 to 410-B of a single bank group 408 (e.g., up to all banks of the bank group), multiple banks distributed across two or more bank groups, a single bank group 408, multiple bank groups 408-1 to 408-G, all banks on an IC chip (and thus all bank groups, if present), and so forth.

### Example Techniques and Hardware

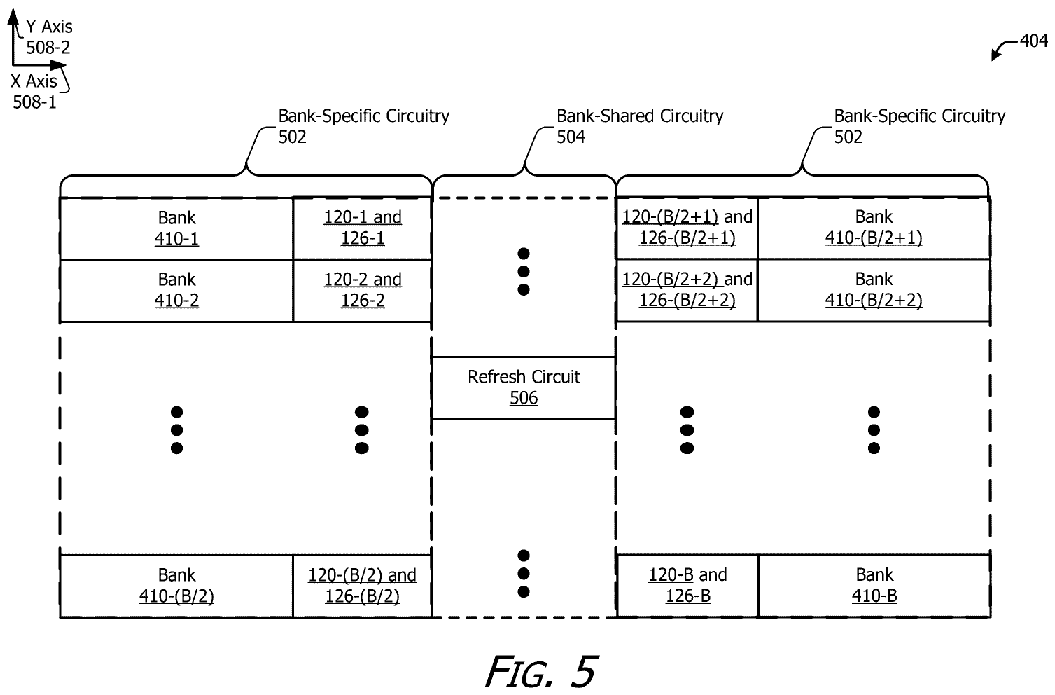

FIG. 5 illustrates an example arrangement of circuits that can implement aspects of sharing a sense amplifier between memory cells of a memory device on a die 404. As shown, the die 404 can include multiple instances of the UBD mitigation circuit 120 and multiple instances of the sense amplifier 126. In example implementations, the die 404 includes bank-specific circuitry 502 and bank-shared circuitry 504. Bank-specific circuitry 502 includes components that are associated with a particular bank 410. For example, the bank-specific circuitry 502 includes the banks 410-1, 410-2, . . . , 410-(B/2), 410-(B/2+1), 410-(B/2+2), . . . , 410-B; the UBD mitigation circuits 120-1, 120-2, . . . , 120-(B/2), 120-(B/2+1), 120-(B/2+2), . . . , 120-B; and the sense amplifier 126-1, 126-2, . . . , 126-(B/2), 126-(B/2+1), 126-(B/2+2), . . . , 126-B.

The UBD mitigation circuits 120-1 to 120-B and the sense amplifiers 126-1 to 126-B are respectively coupled to the banks 410-1 to 410-B. In some cases, subsets of the banks 410-1 to 410-B are associated with different bank groups 408. For example, the die 404 can include 32 banks 410-1 . . . 410-B (e.g., B equals 32 in this example). The 32 banks 410-1 to 410-B can form eight bank groups 408-1 . . . 408-G (e.g., G equals 8 in this example), with each bank group 408 therefore including four of the banks 410. In other cases, the banks 410-1 to 410-B may be part of, or otherwise associated with, a single bank group 408, or the memory die may have no organization by bank group. In some implementations, each of the sense amplifiers 126-1 to 126-B can be shared between two or more memory array portions of their respective banks 410-1 to 410-B. In a particular example, the sense amplifier 126-1 is shared between a first memory cell and a second memory cell of the bank 410-1. In other aspects, each of the banks 410 may include multiple sense amplifiers 126 in which each sense amplifier 126 is shared between multiple memory cells or memory array portions of each bank 410-1 to 410-B.

The bank-shared circuitry 504 includes components that are associated with multiple banks 410, such as two or more banks. These components can perform operations or provide instructions or commands that are associated with multiple banks 410. Example components of the bank-shared circuitry 504 can include at least one error-handling circuit (not shown) and at least one refresh circuit 506. In some architectures, the bank-shared circuitry 504 can be positioned on an IC chip in a centralized portion of the chip. For instance, the bank-shared circuitry 504 can be positioned between two or more banks to facilitate having signaling pathways to the multiple banks with lengths that are more equal than if the bank-shared circuitry 504 were positioned on a far side of the multiple banks.

Further, on the die 404, the bank-specific circuitry 502 can be positioned on two (or more) opposite sides of the bank-shared circuitry 504. Explained another way, the bank-shared circuitry 504 can be centrally positioned on the die 404. As such, the error-handling circuit and the refresh circuit 506 can be positioned closer to the center of the die 404 as compared to the edges of the die 404. Positioning the bank-shared circuitry 504 in the center enables signal routing between the bank-shared circuitry 504 and the bank-specific circuitry 502 to be simplified, shortened, or better equalized.

Consider a first axis 508-1 (e.g., the X axis 508-1) and a second axis 508-2 (e.g., the Y axis 508-2), which is perpendicular to the first axis 508-1. In FIG. 5, the first axis 508-1 is depicted as a “horizontal” axis, and the second axis 508-2 is depicted as a “vertical” axis. Components of the bank-shared circuitry 504 are distributed across the second axis 508-2. A first set of the banks (e.g., banks 410-1 to 410-(B/2)) are arranged along the second axis 508-2 on a “left” side (as depicted) of the bank-shared circuitry 504. A second set of the banks (e.g., banks 410-(B/2+1) to 410-B) are arranged along the second axis 508-2 on a “right” side of the bank-shared circuitry 504. The UBD mitigation circuits 120-1 to 120-B can be positioned between the corresponding banks 410-1 to 410-B and the bank-shared circuitry 504, and at least some of the sense amplifiers 126-1 to 126-B may be positioned between the corresponding banks 410-1 to 410-B and the bank-shared circuitry 504. Additionally or alternatively, at least some of the sense amplifiers 126-1 to 126-B may be positioned between memory sub-arrays “within” a given bank 410. The principles for sharing a sense amplifier between memory cells of a memory device, however, can be implemented in alternative architectures.

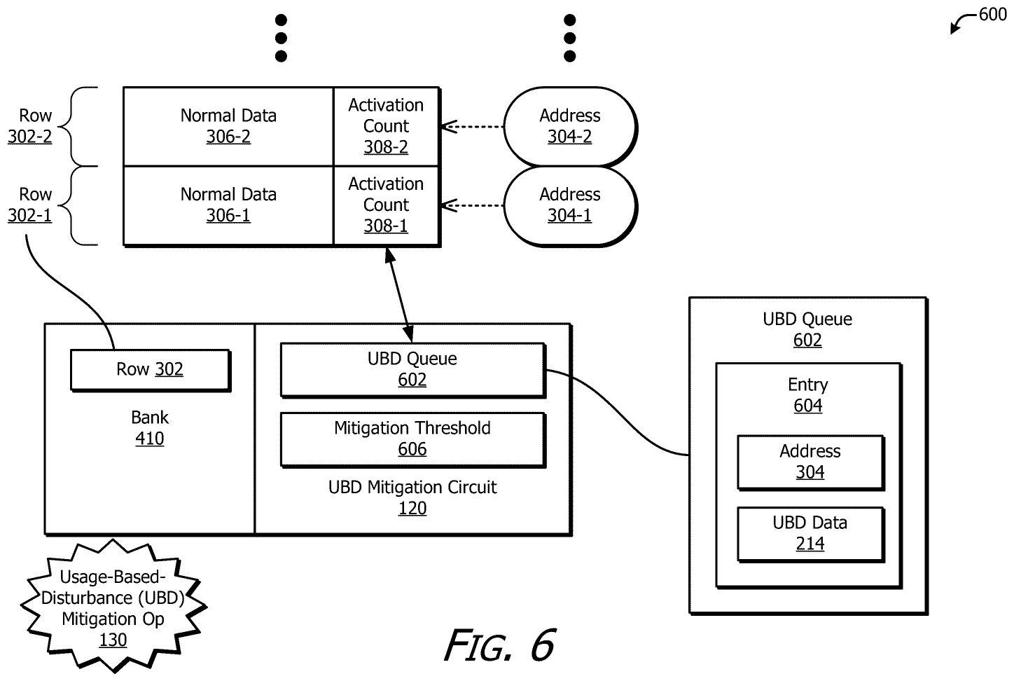

FIG. 6 illustrates, generally at 600, aspects of an example usage-based-disturbance mitigation operation 130 that is performed by an example usage-based-disturbance mitigation circuit 120 to provide example usage-based-disturbance mitigation functionality. As shown, a UBD mitigation circuit 120 corresponds to, or is otherwise associated with, a bank 410. In example implementations, the UBD mitigation circuit 120 can include a usage-based-disturbance queue 602 (UBD queue 602) to facilitate performing the UBD mitigation operation 130. The usage-based-disturbance queue 602 can include multiple entries, such as an entry 604. Each entry 604 can include an address 304 (e.g., at least a row address) of the corresponding row 302 and the usage-based-disturbance data 214 for the corresponding row 302. The usage-based-disturbance data 214 can include, for instance, the activation count 308 for the row 302.

In example operations, the UBD mitigation circuit 120 creates or maintains the usage-based-disturbance queue 602. In some cases, the UBD mitigation circuit 120 adds an entry 604 to the usage-based-disturbance queue 602 responsive to an activation count 308 meeting (e.g., equaling or exceeding) a mitigation threshold 606. For instance, each time a row 302 is accessed (e.g., activated), the UBD mitigation circuit 120 can increment the activation count 308 using an activation count update (ACU) unit (not shown) and compare the incremented activation count 308 to the mitigation threshold 606. If the incremented activation count 308 meets the mitigation threshold 606, then an entry 604 is created and added to the usage-based-disturbance queue 602, with the address 304 of the entry 604 corresponding to the accessed row 302. If there is a preexisting entry 604 for the accessed row 302, the activation count 308 of the usage-based-disturbance data 214 of the preexisting entry 604 can be updated.

The incremented activation count 308 is also returned to the row 302 in association with the normal data 306 of the row 302. Meanwhile, over time, the usage-based-disturbance queue 602 can be managed in any of multiple manners. First, the queue can be operated in a first-in, first-out (FIFO) manner in which an oldest entry 604 is addressed with a UBD mitigation operation 130 before newer entries. Alternatively, entries may be addressed with a UBD mitigation operation 130 based on the corresponding activation count 308, such as the highest activation count 308 being remediated first. Second, if the usage-based-disturbance queue 602 is full and another row 302 is newly identified for admission as a new entry 604, another entry (e.g., the oldest entry or the entry with the lowest activation count) can be replaced. Alternatively, the newly identified row 302 can be added to the usage-based-disturbance queue 602 conditional on its activation count 308 exceeding those counts that are already present in the queue. In other cases, the UBD mitigation circuit 120 can keep a list of entries 604 in the usage-based-disturbance queue 602 based on multiple mitigation thresholds, a recency indication, no mitigation threshold (e.g., the highest activation counts are maintained without regard to a threshold), or some combination thereof.

From time to time, including during the times that are described herein, the UBD mitigation circuit 120 is assigned an opportunity to perform, or is commanded to perform, a UBD mitigation operation 130. If there is no populated or pending entry 604, the UBD mitigation circuit 120-2 can pass or skip the mitigation opportunity. For the UBD mitigation operation 130, the UBD mitigation circuit 120 identifies an entry 604 from the usage-based-disturbance queue 602. The identified entry 604 can be selected based on a FIFO approach, based on which activation count is highest, based on a last-in, first-out (LIFO) approach, and so forth. To mitigate the usage-based-disturbance situation, the UBD mitigation circuit 120 refreshes one or more “victim” rows of the row 302 having the address 304 that is identified in the selected entry 604 and that is the aggressor row in this situation.

The one or more row-based memory-cell refresh operations (or charge restore operations) for the UBD mitigation operation 130 can be performed during one or more refresh-pump time intervals. Responsive to performing the one or more refresh operations, the activation count 308 of the aggressor row 302 can be reset (e.g., to zero). Further, the entry 604 can be removed from the usage-based-disturbance queue 602 physically (e.g., by erasing the data of the entry 604 or changing a pointer structure) or virtually/logically (e.g., by adjusting a flag indicating the validity of the entry 604, such as a valid flag bit). Although certain aspects for a UBD mitigation operation 130 have been described herein, these aspects are set forth by way of example only, for a UBD mitigation operation 130 may be performed in various alternative manners.

FIG. 7 illustrates aspects of an example sense amplifier 126 that can be shared between memory cells of an example memory device circuit 700. As illustrated, the memory device circuit 700 includes a sense amplifier 126 having a sense amplifier core 702, a first terminal 710-1, and a second terminal 710-2. The memory device circuit 700 further includes a first memory cell 704-1 within a first memory array tile (MAT) 706-1 (or other memory array portion, such as a sub-array) and a second memory cell 704-2 within a second MAT 706-2 (or another memory array portion, such as another sub-array). The first memory cell 704-1 is coupled to a first bitline (BL_1) 712-1, and the second memory cell 704-2 is coupled to a second bitline (BL_2) 712-2. For differential memory cells that use two capacitors to store a single bit (e.g., “01” equates to a zero-valued bit, and “10” equates to a one-valued bit), the first memory cell 704-1 is further coupled to a third bitline, or first bitline bar (BLB_1), 712-3, and the second memory cell 704-2 is further coupled to a fourth bitline, or second bitline bar (BLB_2), 712-4.

In example implementations, the memory device circuit 700 also includes a first switching device 708-1 coupled between the first bitline 712-1 and the first terminal 710-1 of the sense amplifier 126 and a second switching device 708-2 coupled between the second bitline 712-2 and the first terminal 710-1 of the sense amplifier 126. For differentially-encoded memory cells 704, the memory device circuit 700 further includes a third switching device 708-3 coupled between the third bitline 712-3 and the second terminal 710-2 of the sense amplifier 126 and a fourth switching device 708-4 coupled between the fourth bitline 712-4 and the second terminal 710-2 of the sense amplifier 126. In some cases, the first, second, third, and fourth switching devices 708-1, 708-2, 708-3, and 708-4 may alternatively be part of the sense amplifier 126 along with the sense amplifier core 702, the first terminal 710-1, and the second terminal 710-2.

The switching devices 708-1 to 708-4 may be physically positioned closer to the sense amplifier core 702 than to either or both the first and second memory cells 704-1 and 704-2. The switching devices 708-1 to 708-4 can therefore also be separate from the first and second memory cells 704-1 and 704-2. Accordingly, each memory cell 704 can include a transistor, in conjunction with a capacitor, that is separate and different from the switching devices 708-1 to 708-4. Further, the switching devices 708-1 to 708-4 can be separate and different from any switches used to activate or precharge a row or rows that include the first and second memory cells 704-1 and 704-2. Each switching device 708 (e.g., the first switching device 708-1) may operate to connect or disconnect a respective memory cell 704 from a terminal 710 of the sense amplifier 126 without impacting whether the terminal 710 of the sense amplifier 126 can be connected or disconnected to a different memory cell 704 by a different switching device (e.g., the second switching device 708-2).

In some aspects, the first memory cell 704-1 and the second memory cell 704-2 are disposed on different sides, such as opposite sides, of the sense amplifier 126. In some aspects, the first memory cell 704-1 is part of a first memory cell array (e.g., a “full” memory cell array, a memory cell sub-array, or a memory array tile (MAT) 706), and the second memory cell 704-2 is part of a second memory cell array. In some implementations, one or more of the first memory cell 704-1 and the second memory cell 704-2 includes a first transistor coupled to a first capacitor and a second transistor coupled to a second capacitor to realize a differential memory cell that uses two voltage values to store one data bit value. Further, in some aspects, the first memory cell 704-1 and the second memory cell 704-2 comprise memory cells configured to store UBD data 214 (e.g., of FIGS. 2, 3, and 6).

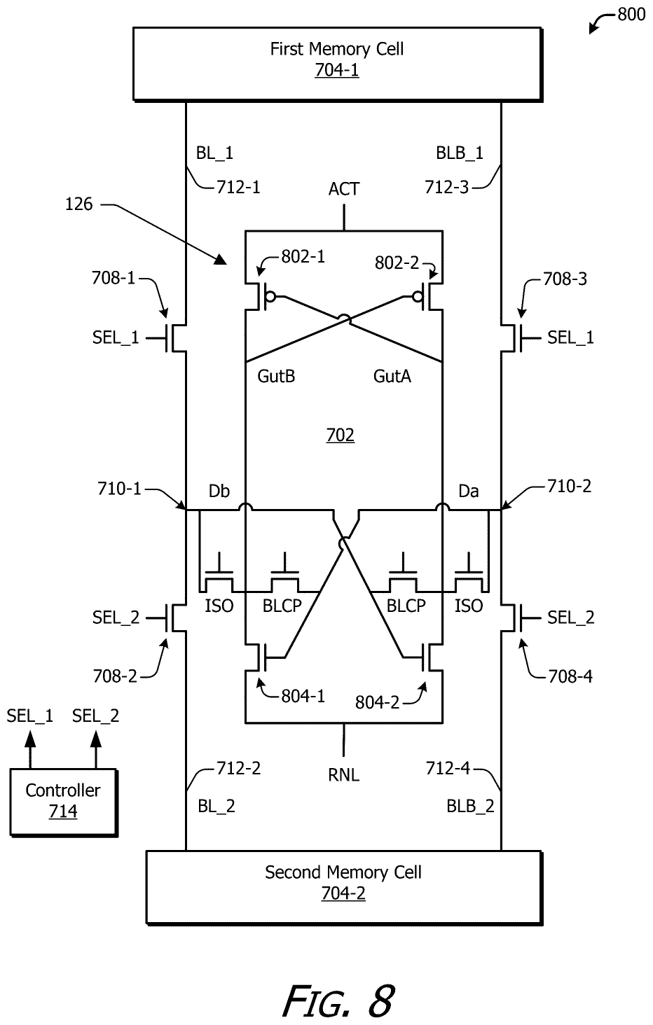

The different aspects and implementations described herein can be combined in any manner. For instance, a memory cell 704 can store UBD data 214 using a differential encoding that is realized with two capacitors and two transistors. Additionally or alternatively, although FIG. 7 is depicted and described in a differential logic context (as is FIG. 8), the principles described herein and illustrated in the accompanying drawings are not so limited. Instead, the sharing of a sense amplifier 126 between two or more memory cells 704 can be implemented in a non-differential manner. For example, the sense amplifier 126 can have a single terminal 710 (instead of first and second terminals 710-1 and 710-2). Similarly, each memory cell 704 may be coupled to a single bitline and can have one capacitor and transistor pair to store one data bit (instead of two transistor-capacitor pairs to store one data bit).

Generally, each switch or switching device 708 can be implemented with at least one transistor. The transistors may be realized with any one or more of multiple transistor types. Examples transistor types include a field effect transistor (FET), a junction FET (JFET), a metal-oxide-semiconductor FET (MOSFET), a bipolar junction transistor (BJT), an insulated-gate bipolar transistor (IGBT), and so forth. Manufacturers may fabricate FETs as n-channel or p-channel transistor types and may fabricate BJTs as NPN or PNP transistor types. Each transistor may include at least one control terminal and one or more channel terminals. With an FET transistor, for example, a control terminal can correspond to a gate terminal, and a channel terminal can correspond to a source terminal or a drain terminal. With a BJT transistor, as another example, a control terminal can correspond to a base terminal, and a channel terminal can correspond to an emitter terminal or a collector terminal.

The first switching device 708-1 and the third switching device 708-3 each include a control terminal configured to receive a first selection signal (SEL_1). Similarly, the second switching device 708-2 and the fourth switching device 708-4 each include a control terminal configured to receive a second selection signal (SEL_2). The first switching device 708-1 and the third switching device 708-3 are configured to selectively connect or disconnect the sense amplifier core 702 to or from the first memory cell 704-1 based on the first selection signal (SEL_1). Similarly, the second switching device 708-2 and the fourth switching device 708-4 are configured to selectively connect or disconnect the sense amplifier core 702 to or from the second memory cell 704-2 based on the second selection signal (SEL_2). In some aspects, during at least some times or time periods, the first selection signal (SEL_1) and the second selection signal (SEL_2) are inverted with respect to one another such that the sense amplifier core 702 is connected to only one of the first memory cell 704-1 or the second memory cell 704-2 at the same time. Accordingly, the sense amplifier core 702 of a single sense amplifier 126 can sense the voltage(s) in one memory cell 704 (e.g., the first memory cell 704-1) without being adversely impacted by voltage(s) in another memory cell 704 (e.g., the second memory cell 704-2), and vice versa.

In an example operation, the first switching device 708-1 is configured to connect the first bitline 712-1 to the first terminal 710-1, and the third switching device 708-3 is configured to connect the third bitline 712-3 to the second terminal 710-2 during a first time period based on the first selection signal (SEL_1). These connections enable the sense amplifier core 702 to sense the two voltages stored in the first memory cell 704-1. Also during the first time period, the second switching device 708-2 is configured to disconnect the second bitline 712-2 from the first terminal 710-1, and the fourth switching device 708-4 is configured to disconnect the fourth bitline 712-4 from the second terminal 710-2 based on the second selection signal (SEL_2). These disconnections isolate the sense amplifier core 702 from the two voltages stored in the second memory cell 704-2. Accordingly, during the first time period, the sense amplifier 126 is configured to read a value stored within the first memory cell 704-1.

During a second time period, the first switching device 708-1 is configured to disconnect the first bitline 712-1 from the first terminal 710-1, and the third switching device 708-3 is configured to disconnect the third bitline 712-3 from the second terminal 710-2 based on the first selection signal (SEL_1). Also during the second time period, the second switching device 708-2 is configured to connect the second bitline 712-2 to the first terminal 710-1, and the fourth switching device 708-4 is configured to connect the fourth bitline 712-4 to the second terminal 710-2. Accordingly, during the second time period, the sense amplifier 126 is configured to read a value stored within the second memory cell 704-2. In some cases, each time period can correspond to a read operation, at least a portion of an amount of time that a respective row is open, some combination thereof, and so forth.

In some aspects, a controller 714 is configured to control the first switching device 708-1, the second switching device 708-2, the third switching device 708-3, and the fourth switching device 708-4 to connect the first terminal 710-1 and the second terminal 710-2 to the first memory cell 704-1 or memory cell array portion and to disconnect the first terminal 710-1 and the second terminal 710-2 from the second memory cell 704-2 or other memory cell array portion during a first time period. The controller is further configured to control the first switching device 708-1, the second switching device 708-2, the third switching device 708-3, and the fourth switching device 708-4 to disconnect the first terminal 710-1 and the second terminal 710-2 from the first memory cell 704-1 or memory cell array portion and connect the first terminal 710-1 and the second terminal 710-2 to the second memory cell 704-2 or other memory cell array portion during a second time period. To do so, the controller 714 can drive voltages on the first and second selection signals (SEL_1 and SEL_2) to turn on or turn off the transistors of the switching devices 708-1 to 708-4.

FIG. 8 illustrates aspects of another example sense amplifier 126 that can be shared between memory cells of a memory device circuit 800. The example memory device circuit 800 is similar to the example memory device circuit 700 shown in FIG. 7 but includes a specific example implementation of a sense amplifier 126. As shown, the sense amplifier core 702 is realized as a differential-voltage sense amplifier; however, the principles are applicable to implementations of a sense amplifier core 702 that sense data bits that are stored as one voltage (instead of being stored using a differential voltage pair).

In example implementations, the sense amplifier 126 includes a first p-type transistor 802-1, a second p-type transistor 802-2, a first n-type transistor 804-1, and a second n-type transistor 804-2. A source terminal of the first p-type transistor 802-1 and a source terminal of the second p-type transistor 802-2 are configured to receive an activation (ACT) signal to provide a supply voltage at an active “high” level. A gate terminal of the first p-type transistor 802-1 is coupled to a drain terminal of the second p-type transistor 802-2 at a first gut node (GutA). A gate terminal of the second p-type transistor 802-2 is coupled to a drain terminal of the first p-type transistor 802-1 at a second gut node (GutB).

The drain terminal of the first p-type transistor 802-1 is coupled to a drain terminal of the first n-type transistor 804-1, and the drain terminal of the second p-type transistor 802-2 is coupled to a drain terminal of the second n-type transistor 804-2. A source terminal of the first n-type transistor 804-1 and a source terminal of the second n-type transistor 804-2 are each coupled to a Row Nsense Latch (RNL) signal that may provide a reference voltage at an active “low” level. A gate terminal of the first n-type transistor 804-1 is coupled to the second terminal 710-2 of the sense amplifier 126 at a first digital line (Da), and a gate terminal of the second n-type transistor 804-2 is coupled to the first terminal 710-1 of the sense amplifier 126 at a second digital line (Db).

A first isolation (ISO) transistor is coupled between the drain terminal of the first n-type transistor 804-1 and the first terminal 710-1. A first bitline clamp (BLCP) transistor is coupled between the gate terminal and the drain terminal of the first n-type transistor 804-1. A second ISO transistor is coupled between the drain terminal of the second n-type transistor 804-2 and the second terminal 710-2. A second BLCP transistor is coupled between the gate terminal and the drain terminal of the second n-type transistor 804-2. The first ISO transistor and the second ISO transistor are each configured to receive an isolation (ISO) control signal, and the first BLCP transistor and the second BLCP transistor are each configured to receive a BLCP control signal. A sense amplifier core 702, however, can include more, fewer, or different transistors, and such transistors may be coupled together in alternative manners.

Similarly to the memory device circuit 700 of FIG. 7, the memory device circuit 800 further includes a first memory cell 704-1 coupled to a first bitline (BL_1) 712-1 and a second memory cell 704-2 coupled to a second bitline (BL_2) 712-2. With a differential architecture, the first memory cell 704-1 is further coupled to a third bitline, or first bitline bar (BLB_1), 712-3, and the second memory cell 704-2 is further coupled to a fourth bitline, or second bitline bar (BLB_2), 712-4. The memory device circuit 800 includes a first switching device 708-1 coupled between the first bitline 712-1 and the first terminal 710-1 of the sense amplifier 126 and a second switching device 708-2 coupled between the second bitline 712-2 and the first terminal 710-1 of the sense amplifier 126. The memory device circuit 800 also includes a third switching device 708-3 coupled between the third bitline 712-3 and the second terminal 710-2 of the sense amplifier 126 and a fourth switching device 708-4 coupled between the fourth bitline 712-4 and the second terminal 710-2 of the sense amplifier 126. Each of the first memory cell 704-1 and the second memory cell 704-2 is configured to use two capacitors to store two voltage levels that jointly represent one logical value.

The first switching device 708-1 and the third switching device 708-3 each include a control terminal configured to receive a first selection signal (SEL_1). Similarly, the second switching device 708-2 and the fourth switching device 708-4 each include a control terminal configured to receive a second selection signal (SEL_2). The first switching device 708-1 and the third switching device 708-3 are configured to selectively connect or disconnect the sense amplifier 126 to or from the first memory cell 704-1 based on the first selection signal (SEL_1). Similarly, the second switching device 708-2 and the fourth switching device 708-4 are configured to selectively connect or disconnect the sense amplifier 126 to or from the second memory cell 704-2 based on the second selection signal (SEL_2). In some aspects, at least a portion of (e.g., at least part of the time) the first selection signal (SEL_1) and the second selection signal (SEL_2) are inverted with respect to one another such that the sense amplifier 126 is only connected to one of the first memory cell 704-1 or the second memory cell 704-2 at the same time.

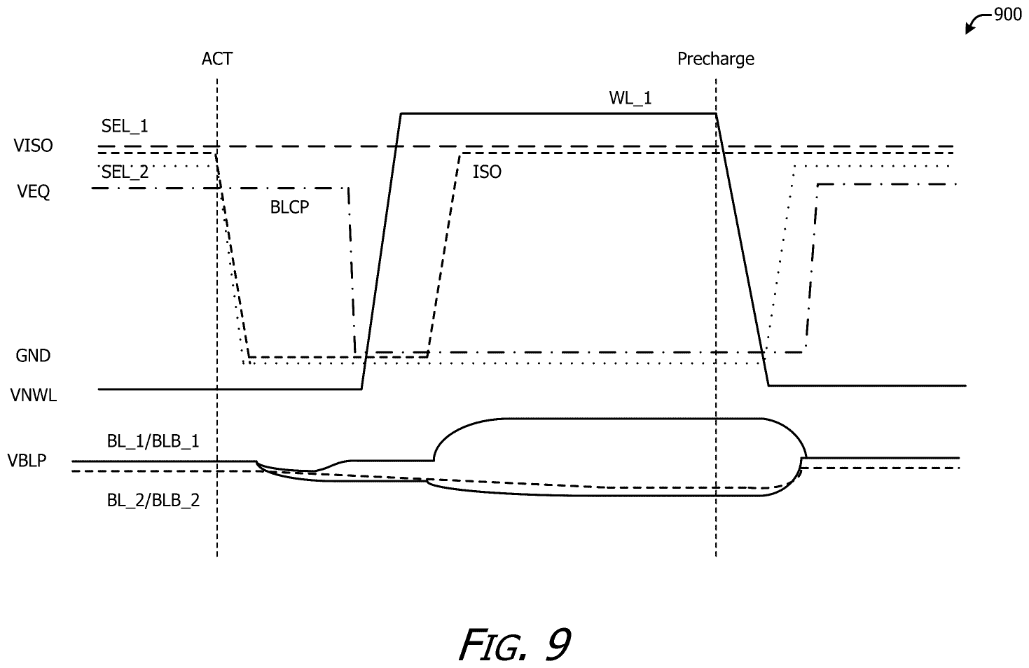

FIG. 9 illustrates an example timing diagram 900 for implementing aspects of sharing a sense amplifier between memory cells of the memory device of FIG. 8. The timing diagram 900 illustrates example values of signals associated with the sense amplifier 126, including SEL_1 (long-dashed line), SEL_2 (dotted line), ISO (short-dashed line), BLCP (dashed and dotted line), a first wordline (WL_1) (solid line), BL_1, BLB_1, BL_2, and BLB_2 signals during a read operation of the first memory cell 704-1. Prior to activation of the first memory cell 704-1, both the SEL_1 and SEL_2 signals are set to high. In addition, the ISO and BLCP voltage levels are set high.

Upon activation for the reading of the first memory cell 704-1, the SEL_2 signal is dropped to low to disconnect the second bitline 712-2 and the fourth bitline 712-4 from the second memory cell 704-2. The ISO signal and the BLCP values are consecutively dropped to a low value prior to the reading of the voltage values stored in the first memory cell 704-1. During this time, the values of BL_2 and BLB_2 will float. The low power values of BL_1 and BLB_1 are read from the first memory cell 704-1 by the sense amplifier 126 and amplified responsive to a high logic level for the WL_1 signal during the row active (tRAS) time period. During the tRAS time period, the ISO signal is raised to a high value. During a precharge period, the values of SEL_1 and SEL_2 are both set to high again, and the value of BLCP likewise returns to high. Accordingly, during the tRAS time period, the values of SEL_1 and SEL_2 are inverted with respect to one another to enable the sense amplifier 126 to sense voltage(s) stored in the first memory cell 704-1 without sensing the voltage(s) stored in the second memory cell 704-2.

### Example Methods

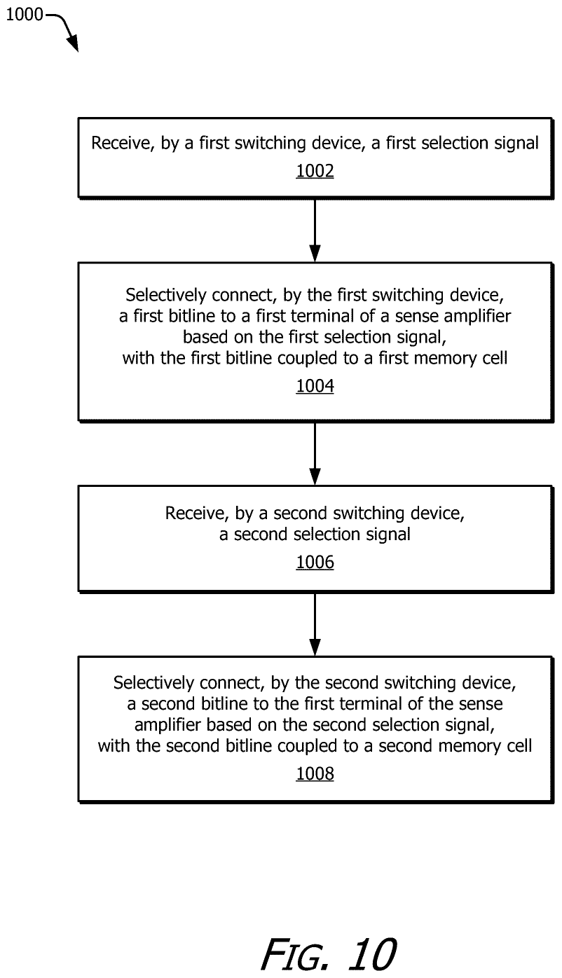

This section describes an example method for implementing aspects of sharing a sense amplifier between memory cells of a memory device with reference to the diagram of FIG. 10. This description may also refer to components, entities, and other aspects depicted in FIGS. 1 to 9 by way of example only.

FIG. 10 illustrates an example method 1000 for implementing aspects of sharing a sense amplifier between memory cells of a memory device. As shown, the method 1000 can include four blocks 1002 to 1008. In some cases, operations of the method 1000 are implemented by a memory device as described with reference to FIGS. 1 to 6. In particular, the operations of the method 1000 can be performed by a memory device circuit as described herein with reference to FIGS. 7 and 8.

At block 1002, a first switching device receives a first selection signal. In a particular example, the first switching device includes the first switching device 708-1, and the first selection signal includes the first selection signal (SEL_1). At block 1004, the first switching device selectively connects a first bitline to a first terminal of a sense amplifier based on the first selection signal, with the first bitline coupled to a first memory cell. In a particular example, the first bitline includes the first bitline 712-1. Further, the sense amplifier can include the sense amplifier 126, and the first terminal can include the first terminal 710-1. Thus, the first bitline 712-1 can be coupled to the first memory cell 704-1.

At block 1006, a second switching device receives a second selection signal. For example, the second switching device 708-2 can receive the second selection signal (SEL_2). In some cases, a controller 714 may use the second selection signal (SEL_2) to open or close the second switching device 708-2 (e.g., to turn off or turn on, respectively, a transistor of the second switching device 708-2). At block 1008, the second switching device selectively connects a second bitline to the first terminal of the sense amplifier based on the second selection signal, with the second bitline being coupled to a second memory cell. For example, the second switching device 708-2 can selectively connect the second bitline 712-2 to the first terminal 710-1 of the sense amplifier 126 based on the second selection signal (SEL_2). Here, the second bitline 712-2 is coupled to a second memory cell 704-2.

In an example aspect, the method 1000 includes connecting, by the first switching device 708-1, the first bitline 712-1 to the first terminal 710-1 of the sense amplifier 126 based on the first selection signal SEL_1 during a first time period. The method 1000 also includes disconnecting, by the second switching device 708-2, the second bitline 712-2 from the first terminal 710-1 of the sense amplifier 126 based on the second selection signal SEL_2 during the first time period. In another example aspect, the method 1000 further includes disconnecting, by the first switching device 708-1, the first bitline 712-1 from the first terminal 710-1 of the sense amplifier 126 based on the first selection signal SEL_1 during a second time period; and connecting, by the second switching device 708-2, the second bitline 712-2 to the first terminal 710-1 of the sense amplifier 126 based on the second selection signal SEL_2 during the second time period. The first time period can be different from the second time period, such as by having at least one non-overlapping temporal portion.

In another example aspect, the method 1000 includes selectively connecting, by a third switching device 708-3, a third bitline 712-3 to a second terminal 710-2 of the sense amplifier 126 based on the first selection signal SEL_1. The third bitline 712-3 is coupled to the first memory cell 704-1. In another example aspect, the method 1000 further includes selectively connecting, by a fourth switching device 708-4, a fourth bitline 712-4 to the second terminal 710-2 of the sense amplifier 126 based on the second selection signal SEL_2. The fourth bitline 712-4 is coupled to the second memory cell 704-2.

In an example aspect, the method 1000 further includes connecting, by the third switching device 708-3, the third bitline 712-3 to the second terminal 710-2 of the sense amplifier 126 based on the first selection signal SEL_1. The method also includes disconnecting, by the fourth switching device 708-4, the fourth bitline 712-4 from the second terminal 710-2 of the sense amplifier 126 based on the second selection signal SEL_2 for at least part of a time period during which the third bitline 712-3 is connected to the second terminal 710-2 of the sense amplifier 126 by the third switching device 708-3.

In another example aspect, the method 1000 further includes connecting, by the fourth switching device 708-4, the fourth bitline 712-4 to the second terminal 710-2 of the sense amplifier 126 based on the second selection signal SEL_2. The method also includes disconnecting, by the third switching device 708-3, the third bitline 712-3 from the second terminal 710-2 of the sense amplifier 126 based on the first selection signal SEL_2 for at least part of a time period during which the fourth bitline 712-4 is connected to the second terminal 710-2 of the sense amplifier 126 by the fourth switching device 708-4.

For the figures described above, the order in which operations are shown and/or described is not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners. Additionally, the processes and the operations thereof across the method of FIG. 10 may be implemented separately or in conjunction with one another.

Aspects of these methods may be implemented in, for example, hardware (e.g., fixed-circuit circuitry or a processor in conjunction with a memory), firmware, or some combination thereof. The method may be realized using one or more of the apparatuses, components, or other aspects shown in FIGS. 1 to 9, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of sharing a sense amplifier between memory cells of a memory device are described:

Example 1: A memory device comprising:
a sense amplifier having a first terminal;
a first bitline;
a first memory cell coupled to the first bitline;
a second bitline;
a second memory cell coupled to the second bitline;
a first switching device coupled between the first bitline and the first terminal of the sense amplifier; and
a second switching device coupled between the second bitline and the first terminal of the sense amplifier.

Example 2: The memory device of example 1 or any other example(s) described herein, wherein:
the first switching device includes a first input coupled to the first bitline and a first output coupled to the first terminal of the sense amplifier; and
the second switching device includes a second input coupled to the second bitline and a second output coupled to the first terminal of the sense amplifier.

Example 3: The memory device of example 1 or any other example(s) described herein, wherein:
the first switching device is configured to selectively connect the first bitline to the first terminal of the sense amplifier based on a first selection signal; and
the second switching device is configured to selectively connect the second bitline to the first terminal of the sense amplifier based on a second selection signal.

Example 4: The memory device of example 3 or any other example(s) described herein, wherein:
a first control terminal of the first switching device is configured to receive the first selection signal; and
a second control terminal of the second switching device is configured to receive the second selection signal.

Example 5: The memory device of example 3 or any other example(s) described herein, wherein:
the first switching device is configured to connect the first bitline to the first terminal of the sense amplifier based on the first selection signal to enable the first memory cell to be read; and
the second switching device is configured to disconnect the second bitline from the first terminal of the sense amplifier based on the second selection signal to enable the first memory cell to be read.

Example 6: The memory device of example 3 or any other example(s) described herein, wherein:
the first switching device is configured to disconnect the first bitline from the first terminal of the sense amplifier based on the first selection signal during a time period; and
the second switching device is configured to connect the second bitline to the first terminal of the sense amplifier based on the second selection signal during the time period.

Example 7: The memory device of example 3 or any other example(s) described herein, further comprising:
a third bitline coupled to the first memory cell;
a third switching device coupled between the third bitline and a second terminal of the sense amplifier;
a fourth bitline coupled to the second memory cell; and
a fourth switching device coupled between the fourth bitline and the second terminal of the sense amplifier.

Example 8: The memory device of example 7 or any other example(s) described herein, wherein:
the third switching device includes a third input coupled to the third bitline and a third output coupled to the second terminal of the sense amplifier; and
the fourth switching device includes a fourth input coupled to the fourth bitline and a fourth output coupled to the second terminal of the sense amplifier.

Example 9: The memory device of example 8 or any other example(s) described herein, wherein:
the first switching device is configured to disconnect the first bitline from the first terminal of the sense amplifier based on the first selection signal during a time period;
the second switching device is configured to connect the second bitline to the first terminal of the sense amplifier based on the second selection signal during the time period;
the third switching device is configured to disconnect the third bitline from the second terminal of the sense amplifier based on the first selection signal during the time period; and
the fourth switching device is configured to connect the fourth bitline to the second terminal of the sense amplifier based on the second selection signal during the time period.

Example 10: The memory device of example 7 or any other example(s) described herein, wherein at least one of the first switching device or the second switching device comprises at least one transistor.

Example 11: The memory device of example 7 or any other example(s) described herein, wherein:
the sense amplifier comprises a differential sense amplifier; and
each of the first memory cell and the second memory cell is configured to store two voltage levels that jointly represent one logical value.

Example 12: The memory device of example 1 or any other example(s) described herein, wherein the first memory cell comprises a first transistor coupled to a first capacitor and a second transistor coupled to a second capacitor.

Example 13: The memory device of example 1 or any other example(s) described herein, wherein the first memory cell is part of a first memory cell array, and the second memory cell is part of a second memory cell array.

Example 14: The memory device of example 13 or any other example(s) described herein, wherein the first memory cell array and the second memory cell array are disposed on opposite sides of the sense amplifier.

Example 15: The memory device of example 13 or any other example(s) described herein, wherein the first memory cell array comprises a first memory array tile, and the second memory cell array comprises a second memory array tile.

Example 16: The memory device of example 1 or any other example(s) described herein, wherein the first memory cell and the second memory cell comprise memory cells configured to store usage-based-disturbance (UBD) data.

Example 17: A method performed by a memory device to share a sense amplifier between memory cells, the method comprising:
receiving, by a first switching device, a first selection signal;
selectively connecting, by the first switching device, a first bitline to a first terminal of a sense amplifier based on the first selection signal, the first bitline coupled to a first memory cell;
receiving, by a second switching device, a second selection signal; and
selectively connecting, by the second switching device, a second bitline to the first terminal of the sense amplifier based on the second selection signal, the second bitline coupled to a second memory cell.

Example 18: The method of example 17 or any other example(s) described herein, further comprising:
connecting, by the first switching device, the first bitline to the first terminal of the sense amplifier based on the first selection signal during a first time period; and
disconnecting, by the second switching device, the second bitline from the first terminal of the sense amplifier based on the second selection signal during the first time period.

Example 19: The method of example 18 or any other example(s) described herein, further comprising:
disconnecting, by the first switching device, the first bitline from the first terminal of the sense amplifier based on the first selection signal during a second time period; and
connecting, by the second switching device, the second bitline to the first terminal of the sense amplifier based on the second selection signal during the second time period.

Example 20: The method of example 17 or any other example(s) described herein, further comprising:
selectively connecting, by a third switching device, a third bitline to a second terminal of the sense amplifier based on the first selection signal, the third bitline coupled to the first memory cell; and
selectively connecting, by a fourth switching device, a fourth bitline to the second terminal of the sense amplifier based on the second selection signal, the fourth bitline coupled to the second memory cell.

Example 21: The method of example 20 or any other example(s) described herein, further comprising:
connecting, by the third switching device, the third bitline to the second terminal of the sense amplifier based on the first selection signal; and
disconnecting, by the fourth switching device, the fourth bitline from the second terminal of the sense amplifier based on the second selection signal for at least part of a first time period during which the third bitline is connected to the second terminal of the sense amplifier by the third switching device.

Example 22: The method of example 21 or any other example(s) described herein, further comprising:
connecting, by the fourth switching device, the fourth bitline to the second terminal of the sense amplifier based on the second selection signal; and
disconnecting, by the third switching device, the third bitline from the second terminal of the sense amplifier based on the first selection signal for at least part of a second time period during which the fourth bitline is connected to the second terminal of the sense amplifier by the fourth switching device.

Example 23: An apparatus comprising:
a sense amplifier including a first terminal and a second terminal;
a first switching device coupled between the first terminal and a first memory array portion;
a second switching device coupled between the first terminal and a second memory array portion;
a third switching device coupled between the second terminal and the first memory array portion; and
a fourth switching device coupled between the second terminal and the second memory array portion.

Example 24: The apparatus of example 23 or any other example(s) described herein, further comprising:
a controller configured to control the first switching device, the second switching device, the third switching device, and the fourth switching device to connect the first terminal and the second terminal to the first memory array portion and disconnect the first terminal and the second terminal from the second memory array portion during a first time period.

Example 25: The apparatus of example 24 or any other example(s) described herein, wherein:
the controller is further configured to control the first switching device, the second switching device, the third switching device, and the fourth switching device to disconnect the first terminal and the second terminal from the first memory array portion and connect the first terminal and the second terminal to the second memory array portion during a second time period, the first time period different from the second time period.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of sharing a sense amplifier between memory cells of a memory device have been described in language specific to certain features and/or methods, the subject of the appended claims is not necessarily limited to the specific features or methods described. Rather, the specific features and methods are disclosed as a variety of example implementations of sharing a sense amplifier between memory cells of a memory device.

What is claimed is:

1. A memory device comprising:
a sense amplifier having a first terminal;
a first bitline;
a first memory cell coupled to the first bitline;
a second bitline;
a second memory cell coupled to the second bitline;
a first switching device coupled between the first bitline and the first terminal of the sense amplifier; and
a second switching device coupled between the second bitline and the first terminal of the sense amplifier.

2. The memory device of claim 1, wherein:
the first switching device includes a first input coupled to the first bitline and a first output coupled to the first terminal of the sense amplifier; and
the second switching device includes a second input coupled to the second bitline and a second output coupled to the first terminal of the sense amplifier.

3. The memory device of claim 1, wherein:
the first switching device is configured to selectively connect the first bitline to the first terminal of the sense amplifier based on a first selection signal; and
the second switching device is configured to selectively connect the second bitline to the first terminal of the sense amplifier based on a second selection signal.

4. The memory device of claim 3, wherein:
a first control terminal of the first switching device is configured to receive the first selection signal; and
a second control terminal of the second switching device is configured to receive the second selection signal.

5. The memory device of claim 3, wherein:
the first switching device is configured to connect the first bitline to the first terminal of the sense amplifier based on the first selection signal to enable the first memory cell to be read; and
the second switching device is configured to disconnect the second bitline from the first terminal of the sense amplifier based on the second selection signal to enable the first memory cell to be read.

6. The memory device of claim 3, wherein:
the first switching device is configured to disconnect the first bitline from the first terminal of the sense amplifier based on the first selection signal during a time period; and
the second switching device is configured to connect the second bitline to the first terminal of the sense amplifier based on the second selection signal during the time period.

7. The memory device of claim 3, further comprising:
a third bitline coupled to the first memory cell;
a third switching device coupled between the third bitline and a second terminal of the sense amplifier;
a fourth bitline coupled to the second memory cell; and
a fourth switching device coupled between the fourth bitline and the second terminal of the sense amplifier.

8. The memory device of claim 7, wherein:
the third switching device includes a third input coupled to the third bitline and a third output coupled to the second terminal of the sense amplifier; and
the fourth switching device includes a fourth input coupled to the fourth bitline and a fourth output coupled to the second terminal of the sense amplifier.

9. The memory device of claim 8, wherein:
the first switching device is configured to disconnect the first bitline from the first terminal of the sense amplifier based on the first selection signal during a time period;
the second switching device is configured to connect the second bitline to the first terminal of the sense amplifier based on the second selection signal during the time period;
the third switching device is configured to disconnect the third bitline from the second terminal of the sense amplifier based on the first selection signal during the time period; and
the fourth switching device is configured to connect the fourth bitline to the second terminal of the sense amplifier based on the second selection signal during the time period.

10. The memory device of claim 7, wherein:
the sense amplifier comprises a differential sense amplifier; and
each of the first memory cell and the second memory cell is configured to store two voltage levels that jointly represent one logical value.

11. The memory device of claim 1, wherein the first memory cell comprises:
a first transistor coupled to a first capacitor; and
a second transistor coupled to a second capacitor.

12. The memory device of claim 1, wherein:
the first memory cell is part of a first memory cell array; and
the second memory cell is part of a second memory cell array.

13. The memory device of claim 1, wherein the first memory cell and the second memory cell comprise memory cells configured to store usage-based-disturbance (UBD) data.

14. A method performed by a memory device to share a sense amplifier between memory cells, the method comprising:
receiving, by a first switching device, a first selection signal;
selectively connecting, by the first switching device, a first bitline to a first terminal of a sense amplifier based on the first selection signal, the first bitline coupled to a first memory cell;
receiving, by a second switching device, a second selection signal; and
selectively connecting, by the second switching device, a second bitline to the first terminal of the sense amplifier based on the second selection signal, the second bitline coupled to a second memory cell.

15. The method of claim 14, further comprising:
connecting, by the first switching device, the first bitline to the first terminal of the sense amplifier based on the first selection signal during a first time period; and
disconnecting, by the second switching device, the second bitline from the first terminal of the sense amplifier based on the second selection signal during the first time period.

16. The method of claim 15, further comprising:
disconnecting, by the first switching device, the first bitline from the first terminal of the sense amplifier based on the first selection signal during a second time period; and
connecting, by the second switching device, the second bitline to the first terminal of the sense amplifier based on the second selection signal during the second time period.

17. The method of claim 14, further comprising:
selectively connecting, by a third switching device, a third bitline to a second terminal of the sense amplifier based on the first selection signal, the third bitline coupled to the first memory cell; and
selectively connecting, by a fourth switching device, a fourth bitline to the second terminal of the sense amplifier based on the second selection signal, the fourth bitline coupled to the second memory cell.

18. An apparatus comprising:
a sense amplifier including a first terminal and a second terminal;
a first switching device coupled between the first terminal and a first memory array portion;
a second switching device coupled between the first terminal and a second memory array portion;
a third switching device coupled between the second terminal and the first memory array portion; and
a fourth switching device coupled between the second terminal and the second memory array portion.

19. The apparatus of claim 18, further comprising:
a controller configured to control the first switching device, the second switching device, the third switching device, and the fourth switching device to connect the first terminal and the second terminal to the first memory array portion and disconnect the first terminal and the second terminal from the second memory array portion during a first time period.

20. The apparatus of claim 19, wherein:
the controller is further configured to control the first switching device, the second switching device, the third switching device, and the fourth switching device to disconnect the first terminal and the second terminal from the first memory array portion and connect the first terminal and the second terminal to the second memory array portion during a second time period, the first time period different from the second time period.
